(19) United States
(12) Patent Application Publication
(10) Pub. No.: US 2025/0048533 A1
(43) Pub. Date: Feb. 6, 2025

(54) MULTILAYER BOARD, MULTILAYER BOARD MODULE, AND ELECTRONIC DEVICE

(71) Applicant: Murata Manufacturing Co., Ltd., Nagaokakyo-shi (JP)

(72) Inventors: Nobuo IKEMOTO, Nagaokakyo-shi (JP); Eiichi TAKATA, Nagaokakyo-shi (JP); Kazuhiro YAMAJI, Nagaokakyo-shi (JP); Hideki UEDA, Nagaokakyo-shi (JP)

(21) Appl. No.: 18/925,492

(22) Filed: Oct. 24, 2024

Related U.S. Application Data
(63) Continuation of application No. PCT/JP2023/018517, filed on May 18, 2023.

(30) Foreign Application Priority Data
Jun. 24, 2022 (JP) 2022-101858

(51) Int. Cl. H05K 1/02; H05K 1/11

(52) U.S. Cl. CPC H05K 1/0206; H05K 1/113; H05K 2201/09527; H05K 2201/096; H05K 2201/09609; H05K 2201/09618; H05K 2201/09727; H05K 2201/09827; H05K 2201/10098

(57) ABSTRACT

In a multilayer board, conductor layers include a first conductor layer including a mounting electrode on a positive main surface of an insulator layer located farthest in a Z-axis positive direction of insulator layers. One or more first interlayer connection conductors connect two of the conductor layers located on a positive main surface and a negative main surface of a first insulator layer. The one or more first interlayer connection conductors each include a first region and a second region with a lower thermal conductivity than the first region and located on a Z-axis negative direction side of the first region. The one or more first interlayer connection conductors include one or more large-area first interlayer connection conductors with a larger area than a second interlayer connection conductor when viewed in a Z-axis direction.

### CROSS REFERENCE TO RELATED APPLICATIONS

This application claims the benefit of priority to Japanese Patent Application No. 2022-101858 filed on Jun. 24, 2022 and is a Continuation Application of PCT Application No. PCT/JP2023/018517 filed on May 18, 2023. The entire contents of each application are hereby incorporated herein by reference.

### BACKGROUND OF THE INVENTION

### 1. Field of the Invention

The present invention relates to multilayer boards each including an interlayer connection conductor, multilayer board modules, and electronic devices.

### 2. Description of the Related Art

As an invention related to a multilayer board in the relater art, for example, the power amplifier module described in Japanese Unexamined Patent Application Publication No. 2005-191435 is known. This power amplifier module includes a multilayer board and an electronic component. The multilayer board has a structure including a core board and board materials laminated in the up-down direction. The multilayer board has a plate shape having an upper main surface and a lower main surface. The multilayer board includes a plurality of heat dissipation vias extending through the core board and the board materials in the up-down direction. The electronic component is mounted on the upper main surface of the multilayer board. With this configuration, heat generated in the electronic component is transferred to the lower main surface of the multilayer board through the plurality of heat dissipation vias.

In the field of the power amplifier module described in Japanese Unexamined Patent Application Publication No. 2005-191435, there are cases in which heat transfer to the lower surface of the multilayer board is undesirable.

### SUMMARY OF THE INVENTION

Example embodiments of the present invention provide multilayer boards, multilayer board modules, and electronic devices, each of which is able to decrease the amount of heat transferred to a lower surface of the multilayer body while reducing or preventing deterioration of a heat dissipation characteristic.

A multilayer board according to an example embodiment of the present invention includes a multilayer body including a plurality of insulator layers laminated in a Z-axis direction and including a positive main surface located on a Z-axis positive direction side and a negative main surface located on a Z-axis negative direction side, a plurality of conductor layers in or on the multilayer body and including a first conductor layer including a mounting electrode located on a positive main surface of an insulator layer located farthest in a Z-axis positive direction out of the plurality of insulator layers, one or more first interlayer connection conductors extending through a first insulator layer included in the plurality of insulator layers in the Z-axis direction and connecting two of the conductor layers located on a positive main surface and a negative main surface of the first insulator layer, and a second interlayer connection conductor extending through one of the plurality of insulator layers in the Z-axis direction. Each of the one or more first interlayer connection conductors includes a first region, and a second region with lower thermal conductivity than the first region and located on the Z-axis negative direction side of the first region. The one or more first interlayer connection conductors include one or more large-area first interlayer connection conductors with a larger area than the second interlayer connection conductor when viewed in the Z-axis direction.

In the multilayer boards according to example embodiments of the present invention, it is possible to decrease the amount of heat transferred to a lower surface of a multilayer body while reducing or preventing deterioration of a heat dissipation characteristic.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a sectional view of an electronic device 1 according to an example embodiment of the present invention.

FIG. 2 is a top view of a multilayer board 11 and an electronic component 100 according to an example embodiment of the present invention.

FIG. 3 is a sectional view of a multilayer board module 10a according to an example embodiment of the present invention.

FIG. 4 is a sectional view of a multilayer board module 10b according to an example embodiment of the present invention.

FIG. 5 is a sectional view of a multilayer board module 10c according to an example embodiment of the present invention.

FIG. 6 is a sectional view of a multilayer board module 10d according to an example embodiment of the present invention.

FIG. 7 is a sectional view of a multilayer board module 10e according to an example embodiment of the present invention.

FIG. 8 is a sectional view of a multilayer board module 10f according to an example embodiment of the present invention.

FIG. 9 is a sectional view of a multilayer board module 10g according to an example embodiment of the present invention.

FIG. 10 is a sectional view of a multilayer board module 10h according to an example embodiment of the present invention.

FIG. 11 is a sectional view of a multilayer board module 10i according to an example embodiment of the present invention.

FIG. 12 is a sectional view of a multilayer board module 10j according to an example embodiment of the present invention.

FIG. 13 is a sectional view of a multilayer board module 10k according to an example embodiment of the present invention.

FIG. 14 is a sectional view of a multilayer board module 10l according to an example embodiment of the present invention.

FIG. 15 is a top view of a multilayer board 11l according to an example embodiment of the present invention.

FIG. 16 is a top view of a multilayer board 11m according to an example embodiment of the present invention.

FIG. 17 is a sectional view of an electronic device in according to an example embodiment of the present invention.

### DETAILED DESCRIPTION OF THE EXAMPLE EMBODIMENTS

### Example Embodiments

### Structure of Electronic Device

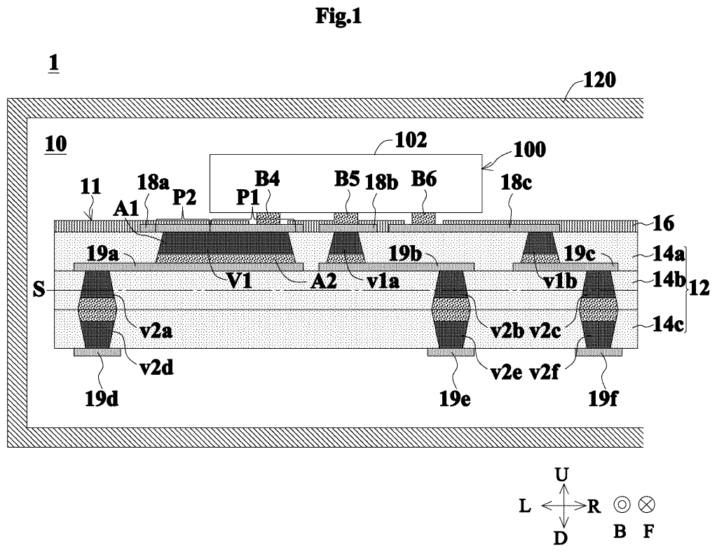

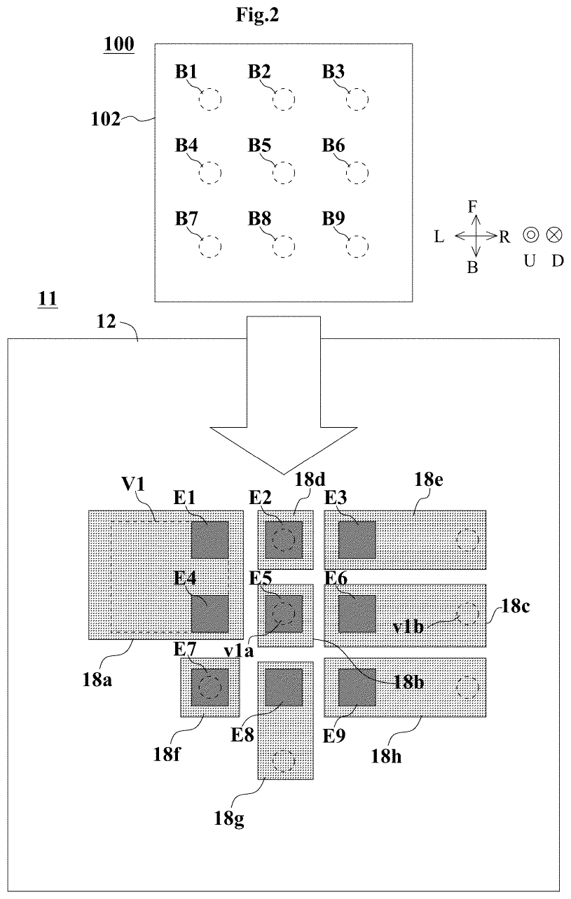

Hereinafter, the structure of an electronic device 1 according to an example embodiment of the present invention will be described with reference to drawings. FIG. 1 is a sectional view of the electronic device 1. FIG. 2 is a top view of a multilayer board 11 and an electronic component 100. In FIG. 2, illustration of a protective layer 16 is omitted.

In this specification, directions are defined as follows. The lamination direction of a multilayer body 12 of the multilayer board 11 is defined as the up-down direction. The up-down direction corresponds to the Z-axis direction. The upward direction corresponds to the Z-axis positive direction. The downward direction corresponds to the Z-axis negative direction. The directions orthogonal or substantially orthogonal to the up-down direction are defined as the right-left direction and the front-rear direction. The right-left direction is orthogonal or substantially orthogonal to the front-rear direction. The upward direction and the downward direction of the up-down direction may be interchanged, the left direction and the right direction of the right-left direction may be interchanged, and the front direction and the rear direction of the front-rear direction may be interchanged.

The electronic device 1 is, for example, a wireless communication terminal such as a smartphone, for example. The electronic device 1 includes a multilayer board module 10 and a housing 120. The multilayer board module 10 includes the multilayer board 11 and the electronic component 100. The housing 120 houses the multilayer board module 10.

The multilayer board 11 transmits radio frequency signals. As illustrated in FIGS. 1 and 2, the multilayer board 11 includes the multilayer body 12, the protective layer 16, conductor layers 18a to 18h and 19a to 19f, first interlayer connection conductors V1, v1a, and v1b, and second interlayer connection conductors v2a to v2f.

As illustrated in FIG. 1, the multilayer body 12 has a plate shape including an upper main surface and a lower main surface. The multilayer body 12 has a rectangular or substantially rectangular shape when viewed in the up-down direction. The multilayer body 12 has a structure including insulator layers 14a to 14c laminated in the up-down direction (the Z-axis direction), each insulator layer including an upper main surface (a positive main surface on the Z-axis positive direction side) and a lower main surface (a negative main surface on the Z-axis negative direction side). The insulator layers 14a to 14c are located in this order from the top to the bottom. The insulator layers 14a to 14c have a rectangular or substantially rectangular shape when viewed in the up-down direction. The material of the insulator layers 14a to 14c is a resin, for example. The material of the insulator layers 14a to 14c is, for example, a thermoplastic resin. The thermoplastic resin is, for example, a liquid crystal polymer. Thus, the multilayer body 12 has flexibility. The plane located at the center of the multilayer body 12 in the up-down direction (the Z-axis direction) and orthogonal or substantially orthogonal to the up-down direction (the Z-axis direction) is defined as an intermediate plane S.

As illustrated in FIGS. 1 and 2, the conductor layers 18a to 18h and 19a to 19f are provided in or on the multilayer body 12. The conductor layers 18a to 18h are located on the upper main surface of the insulator layer 14a. As illustrated in FIG. 2, the conductor layers 18a to 18h include mounting electrodes E1 to E9. The mounting electrodes E1 to E9 are located on the upper main surface (the positive main surface) of the insulator layer 14a located highest (farthest in the Z-axis positive direction) of the insulator layers 14a to 14c. The mounting electrodes E1 to E9 are exposed portions of the conductor layers 18a to 18h on which the protective layer 16 described later is not present. The mounting electrodes E1 to E9 when viewed in the up-down direction are arranged in a 3×3 matrix shape, for example. Each of the mounting electrodes E1 to E9 has a rectangular or substantially rectangular shape when viewed in the up-down direction.

As illustrated in FIG. 2, the conductor layers 18a to 18c are located in this order from the left to the right. The conductor layer 18a extends in the right-left direction. The mounting electrodes E1 and E4 are located in this order from the front to the rear in the right end portion of the conductor layer 18a. The conductor layer 18b has a square or substantially square shape. The mounting electrode E5 is located at the center or approximate center of the conductor layer 18b. The conductor layer 18c extends in the right-left direction. The mounting electrode E6 is located in the left end portion of the conductor layer 18c.

As illustrated in FIG. 1, the conductor layers 19a to 19c are located on the upper main surface of the insulator layer 14b. The conductor layers 19a to 19c are located in this order from the left to the right. The conductor layers 19a to 19c extend in the right-left direction.

As illustrated in FIG. 1, the conductor layers 19d to 19f are located on the lower main surface of the insulator layer 14c. The conductor layers 19d to 19f are located in this order from the left to the right. The conductor layers 19d to 19f have a rectangular or substantially rectangular shape when viewed in the up-down direction. The conductor layers 19d to 19f are, for example, outer electrodes.

The conductor layers 18a to 18c and 19a to 19f as described above are formed by, for example, patterning metal foils attached to the upper main surfaces of the insulator layers 14a and 14b and the lower main surface of the insulator layer 14c. The metal foils are, for example, copper foils.

As illustrated in FIG. 1, the protective layer 16 covers the entire or approximately the entire surface of the upper main surface of the insulator layer 14a. With this, the protective layer 16 protects the conductor layers 18a to 18h. However, the mounting electrodes E1 to E9 are not covered with the protective layer 16. The protective layer 16 is not a portion of the multilayer body 12. Conductor layers are not provided on the upper main surface of the protective layer 16. The protective layer 16 as described above is, for example, a resist layer.

The first interlayer connection conductors V1, v1a, and v1b extend through the insulator layer 14a (the first insulator layer), which is one of the insulator layers 14a to 14c, in the up-down direction (the Z-axis direction). The first interlayer connection conductor V1 (the large-area first interlayer connection conductor) and the first interlayer connection conductors v1a and v1b are located higher than (on the Z-axis positive direction side of) the intermediate plane S. The first interlayer connection conductors V1, v1a, and v1b have shapes the sectional area of which orthogonal or substantially orthogonal to the up-down direction decreases from the bottom to the top. Specifically, for example, the first interlayer connection conductor V1 has a truncated square pyramid shape. The first interlayer connection conductors v1a and v1b have, for example, a truncated cone shape. Thus, in each of the first interlayer connection conductors V1, v1a, and v1b, the area of the upper end is smaller than the area of the lower end.

The first interlayer connection conductor V1 connects the conductor layer 18a and the conductor layer 19a (two conductor layers) located on the upper main surface (the positive main surface) and the lower main surface (the negative main surface), respectively, of the insulator layer 14a (the first insulator layer). The first interlayer connection conductor v1a connects the conductor layer 18b and the conductor layer 19b (two conductor layers) located on the upper main surface (the positive main surface) and the lower main surface (the negative main surface), respectively, of the insulator layer 14a (the first insulator layer). The first interlayer connection conductor v1b connects the conductor layer 18c and the conductor layer 19c (two conductor layers) located on the upper main surface (the positive main surface) and the lower main surface (the negative main surface), respectively, of the insulator layer 14a (the first insulator layer).

Each of the first interlayer connection conductors V1, v1a, and v1b includes a first region A1 and a second region A2. The first region A1 and the second region A2 are located in this order from the top to the bottom. The second region A2 is located lower than (on the Z-axis negative direction side of) the first region A1. The second region A2 has lower thermal conductivity than the first region A1. The material of the first region A1 mentioned above is the same as that of the conductor layers 18a to 18c. Thus, the material of the first region A1 is, for example, copper. The material of the second region A2 is, for example, an alloy including tin and copper or an alloy including tin and silver. The second region A2 is formed by, for example, sintering a conductive paste, a mixture of metal powder and resin.

The second interlayer connection conductors v2a to v2c extend through the insulator layer 14b (one of the insulator layers) in the up-down direction (the Z-axis direction). The second interlayer connection conductors v2a to v2c have a shape the sectional area of which orthogonal or substantially orthogonal to the up-down direction decreases from the bottom to the top. Specifically, the second interlayer connection conductors v2a to v2c have a truncated cone shape. Thus, in each of the second interlayer connection conductors v2a to v2c, the area of the upper end is smaller than the area of the lower end.

The upper end of the second interlayer connection conductor v2a is connected to a left end portion of the conductor layer 19a. The upper end of the second interlayer connection conductor v2b is connected to a right end portion of the conductor layer 19b. The upper end of the second interlayer connection conductor v2c is connected to a right end portion of the conductor layer 19c.

Each of the second interlayer connection conductors v2a to v2c includes a first region A1 and a second region A2. The first region A1 and the second region A2 are located in this order from the top to the bottom.

The second interlayer connection conductors v2d to v2f extend through the insulator layer 14c (one of the insulator layers) in the up-down direction (the Z-axis direction). The second interlayer connection conductors v2d to v2f are located lower than (on the Z-axis negative direction side of) the intermediate plane S. The second interlayer connection conductors v2d to v2f have a shape the sectional area of which orthogonal to the up-down direction decreases from the top to the bottom. Specifically, the second interlayer connection conductors v2d to v2f have a truncated cone shape. Thus, in each of the second interlayer connection conductors v2d to v2f, the area of the upper end is larger than the area of the lower end.

The second interlayer connection conductor v2d connects the second interlayer connection conductor v2a and the conductor layer 19d. The second interlayer connection conductor v2e connects the second interlayer connection conductor v2b and the conductor layer 19e. The second interlayer connection conductor v2f connects the second interlayer connection conductor v2c and the conductor layer 19f.

Each of the second interlayer connection conductors v2d to v2f includes a first region A1 and a second region A2. The first region A1 and the second region A2 are located in this order from the bottom to the top.

The first regions A1 are formed by, for example, plating through holes, extending through the insulator layers 14a to 14c in the up-down direction, with a metal. The metal is, for example, copper. The second regions A2 are formed by, for example, filling metal-plated through holes with a conductive paste and sintering the conductive paste.

The electronic component 100 is mounted on the mounting electrodes E1 to E9 of the multilayer board 11. The electronic component 100 is an element that generates heat while operating. The electronic component 100 is, for example, an integrated circuit (IC). The electronic component 100 is, for example, a radio frequency integrated circuit (RFIC), a central processing unit (CPU), or a power supply IC. The electronic component 100 includes a component body 102 and outer electrodes B1 to B9. The component body 102 has a rectangular or substantially rectangular parallelepiped shape. The outer electrodes B1 to B9 are located on the lower surface of the component body 102. The outer electrodes B1 to B9 are arranged in a 3×3 matrix shape, for example. The outer electrodes B1 to B9 are connected to the mounting electrodes E1 to E9, respectively. The outer electrodes B1 to B9 include electrodes connected to a power supply voltage and the ground potential and electrodes through which radio frequency signals are inputted and outputted. In the present example embodiment, the outer electrode B4 is an electrode to which a power supply voltage or the ground potential is connected.

The first interlayer connection conductor V1 is a large-area first interlayer connection conductor. When viewed in the up-down direction (the Z-axis direction), the first interlayer connection conductor V1 (the large-area first interlayer connection conductor) has larger area than each of the first interlayer connection conductors v1a and v1b and the second interlayer connection conductors v2a to v2f. The first interlayer connection conductor V1 (the large-area first interlayer connection conductor) is directly connected to the conductor layer 18a (the first conductor layer). Specifically, the upper end of the first interlayer connection conductor V1 is in contact with the conductor layer 18a. The first interlayer connection conductor V1 (the large-area first interlayer connection conductor) includes an overlapping portion P1 overlapping the electronic component 100 when viewed in the up-down direction (the Z-axis direction) and a non-overlapping portion P2 not overlapping the electronic component 100 when viewed in the up-down direction (the Z-axis direction).

The first interlayer connection conductor V1 is electrically connected to the outer electrode B4 with the conductor layer 18a interposed therebetween. The outer electrode B4 is an electrode to which a power supply voltage or the ground potential is connected. Thus, the power supply voltage or the ground potential is connected to the first interlayer connection conductor V1 (the large-area first interlayer connection conductor).

### Advantageous Effects

(a) In the multilayer board 11, it is possible to decrease the amount of the heat transferred to the lower surface of the multilayer body 12 while reducing or preventing deterioration of the heat dissipation characteristic. To be more specific, the first interlayer connection conductor V1 (the large-area first interlayer connection conductor) is directly connected to the conductor layer 18a (the first conductor layer). Thus, heat generated in the electronic component 100 is transferred to the first interlayer connection conductor V1 through the conductor layer 18a. The first interlayer connection conductor V1 (the large-area first interlayer connection conductor) includes the first region A1 and the second region A2 having lower thermal conductivity than the first region A1 and located lower than the first region A1. This makes it difficult for the heat transferred to the first interlayer connection conductor V1 to be transferred from the first region A1 to the second region A2. Thus, it is difficult for heat generated in the electronic component 100 to be transferred to the lower surface of the multilayer body 12.

In addition, the first interlayer connection conductor V1 (the large-area first interlayer connection conductor) has a larger area than each of the second interlayer connection conductors v2a to v2c when viewed in the up-down direction. Thus, when heat generated in the electronic component 100 is transferred to the first interlayer connection conductor V1, the heat is transferred in the front-rear direction and the right-left direction in the first region A1. This reduces or prevents deterioration of the heat dissipation characteristic in the multilayer board 11.

(b) In the multilayer board 11, each of the second interlayer connection conductors v2a to v2f has smaller area than the first interlayer connection conductor V1 (the large-area first interlayer connection conductor). Use of small second interlayer connection conductors v2a to v2f as described above increases the wiring density inside the multilayer board 11.

(c) The multilayer board 11 has flexibility. Thus, the multilayer board 11 can be bent and located to conform to members in the electronic device 1. Thus, heat generated in the electronic component 100 is transferred from the multilayer board 11 to the members inside the electronic device 1. This improves the heat dissipation characteristic of the multilayer board 11.

(d) In the multilayer board 11, the following factors also improve the heat dissipation characteristic of the multilayer board 11. To be more specific, the first interlayer connection conductor V1 (the large-area first interlayer connection conductor) includes the overlapping portion P1 overlapping the electronic component 100 when viewed in the up-down direction and the non-overlapping portion P2 not overlapping the electronic component 100 when viewed in the up-down direction. Heat transferred to the first interlayer connection conductor V1 is transferred to the portion of the multilayer body 12 not overlapping the electronic component 100 when viewed in the up-down direction. This makes it less likely that heat is hindered by the electronic component 100 from being radiated from the multilayer body 12 into the atmosphere.

(e) In the multilayer board 11, for example, a power supply voltage or the ground potential is connected to the first interlayer connection conductor V1. Since the resistance of the first interlayer connection conductor V1 is low, heat generation in the first interlayer connection conductor V1 is low. In addition, the characteristic impedance of a conductor connected to a power supply voltage or the ground potential need not match a desired characteristic impedance (for example, about 50 ohms). Thus, it is easy to use the first interlayer connection conductor V1 having a large area as a conductor connected to a power supply voltage or the ground potential.

### First Modified Example

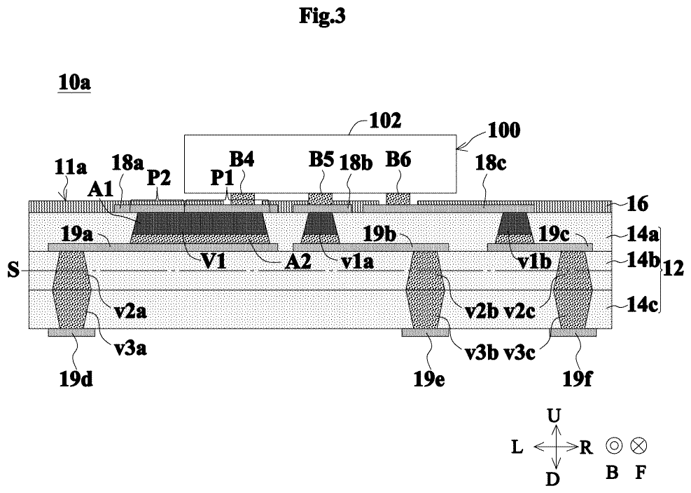

A multilayer board 11a according to a first modified example of an example embodiment of the present invention will be described below with reference to the drawings. FIG. 3 is a sectional view of a multilayer board module 10a.

The multilayer board 11a differs from the multilayer board 11 in the following points.
Second interlayer connection conductors v2a to v2c have lower thermal conductivity than the first regions A1.
The multilayer board 11a includes third interlayer connection conductors v3a to v3c instead of the second interlayer connection conductors v2d to v2f. The third interlayer connection conductors v3a to v3c have lower thermal conductivity than the first regions A1.

The material of the second interlayer connection conductors v2a to v2c and the material of the third interlayer connection conductors v3a to v3c are, for example, an alloy including tin and copper or an alloy including tin and silver. The second interlayer connection conductors v2a to v2c and the third interlayer connection conductors v3a to v3c are formed by, for example, filling through holes with a conductive paste and sintering the conductive paste. The other structure of the multilayer board 11a is the same or substantially the same as that of the multilayer board 11, and thus description thereof is omitted. The multilayer board 11a is capable of providing the advantageous effects (a) to (e).

(f) In the multilayer board 11a, it is possible to reduce the heat transferred to the lower surface of the multilayer body 12. To be more specific, the third interlayer connection conductors v3a to v3c are located lower than (on the Z-axis negative direction side of) the intermediate plane S. The third interlayer connection conductors v3a to v3c have lower thermal conductivity than the first regions A1. This makes it difficult for heat to be transferred to the lower surface of the multilayer body 12 through the third interlayer connection conductors v3a to v3c.

### Second Modified Example

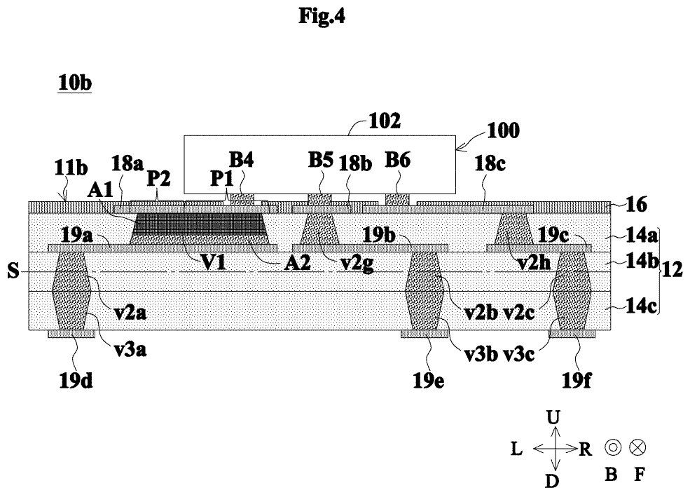

A multilayer board lib according to a second modified example of an example embodiment of the present invention will be described below with reference to the drawings. FIG. 4 is a sectional view of a multilayer board module 10b.

The multilayer board lib differs from the multilayer board 11a in that the multilayer board lib includes second interlayer connection conductors v2g and v2h instead of the first interlayer connection conductors v1a and v1b. The second interlayer connection conductors v2g and v2h have thermal conductivity different from that of the first interlayer connection conductors v1a and v1b. Specifically, the second interlayer connection conductors v2g and v2h have lower thermal conductivity than the first regions A1. The material of the second interlayer connection conductors v2g and v2h is, for example, an alloy containing tin and copper or an alloy containing tin and silver. The second interlayer connection conductors v2g and v2h are formed by, for example, filling through holes with a conductive paste and sintering the conductive paste. The other structure of the multilayer board lib is the same or substantially the same as that of the multilayer board 11a, and thus description thereof is omitted. The multilayer board lib is capable of providing the advantageous effects (a) to (f).

### Third Modified Example

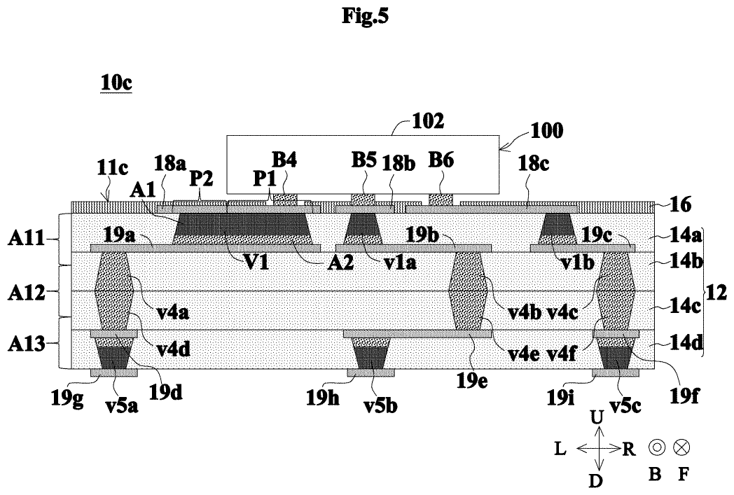

A multilayer board 11c according to a third modified example of an example embodiment of the present invention will be described below with reference to the drawings. FIG. 5 is a sectional view of a multilayer board module 10c.

The multilayer board 11c differs from the multilayer board 11 in the following points.
The multilayer board 11c includes fourth interlayer connection conductors v4a to v4f instead of the second interlayer connection conductors v2a to v2f.
The multilayer body 12 further includes an insulator layer 14d located under the insulator layer 14c.
The multilayer board 11c further includes fifth interlayer connection conductors v5a to v5c.

The multilayer body 12 is trisected in the up-down direction (the Z-axis direction) into a positive region A11, an intermediate region A12, and a negative region A13. The positive region A11, the intermediate region A12, and the negative region A13 are located in this order in the downward direction (the Z-axis negative direction). The first interlayer connection conductor V1 (the large-area first interlayer connection conductor) is located in the positive region A11. To be more accurate, the entire or substantially the entire portion of the first interlayer connection conductor V1 (the large-area first interlayer connection conductor) is located in the positive region A11.

The fourth interlayer connection conductors v4a to v4c extend through the insulator layer 14b (one of the insulator layers) in the up-down direction (the Z-axis direction). The fourth interlayer connection conductors v4d to v4f extend through the insulator layer 14c (one of the insulator layers) in the up-down direction (the Z-axis direction). The fourth interlayer connection conductors v4a to v4f are located in the intermediate region A12. To be more accurate, portions of the fourth interlayer connection conductors v4a to v4f are located in the intermediate region A12. The fourth interlayer connection conductors v4a to v4f have lower thermal conductivity than the first regions A1.

The fifth interlayer connection conductors v5a to v5c extend through the insulator layer 14d (one of the insulator layers) in the up-down direction (the Z-axis direction). The fifth interlayer connection conductors v5a to v5c are located in the negative region A13. To be more accurate, the entire or substantially the entire portions of the fifth interlayer connection conductors v5a to v5c are located in the negative region A13. The fifth interlayer connection conductors v5a to v5c have higher thermal conductivity than the second regions A2. Each of the fifth interlayer connection conductors v5a to v5c includes a first region A1 and a second region A2. The other structure of the multilayer board 11c is the same or substantially the same as that of the multilayer board 11, and thus description thereof is omitted. The multilayer board 11c is capable of providing the advantageous effects (a) to (f).

(g) As for the multilayer board 11c, in the case in which a heat source is in contact with the lower main surface of the multilayer board 11c, heat is diffused inside the multilayer board 11c due to the fifth interlayer connection conductors v5a to v5c. This improves the heat dissipation characteristic of the multilayer board 11c.

(h) In the multilayer board 11c, the fifth interlayer connection conductors v5a to v5c have a structure symmetric or substantially symmetric with the first interlayer connection conductors v1a and v1b in the up-down direction. This makes the overall structure of the multilayer board 11c close to a symmetric structure in the up-down direction. This makes the occurrence of a warp of the multilayer board 11c less likely.

### Fourth Modified Example

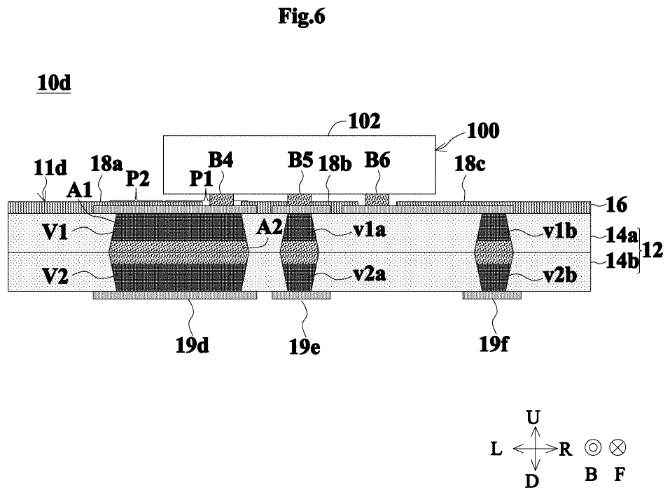

A multilayer board 11d according to a fourth modified example of an example embodiment of the present invention will be described below with reference to the drawings. FIG. 6 is a sectional view of a multilayer board module 10d.

The multilayer board 11d includes a multilayer body 12, a protective layer 16, and first and second interlayer connection conductors V1, v1a, v1b, V2, v2a, and v2b. The multilayer body 12 has a structure including insulator layers 14a and 14b laminated in the up-down direction. The first interlayer connection conductors V1, v1a, and v1b extend through the insulator layer 14a in the up-down direction.

The second interlayer connection conductors V2, v2a, and v2b extend through the insulator layer 14b in the up-down direction. The second interlayer connection conductors V2, v2a, and v2b have a structure symmetric or substantially symmetric with the first interlayer connection conductors V1, v1a, and v1b in the up-down direction. The second interlayer connection conductors V2, v2a, and v2b are electrically connected to the first interlayer connection conductors V1, v1a, and v1b, respectively.

The multilayer board 11d as described above is capable of providing the advantageous effects (a) to (e). In addition, the multilayer board 11d is capable of providing the advantageous effects (g) and (h) with fewer layers than the multilayer board 11c.

### Fifth Modified Example

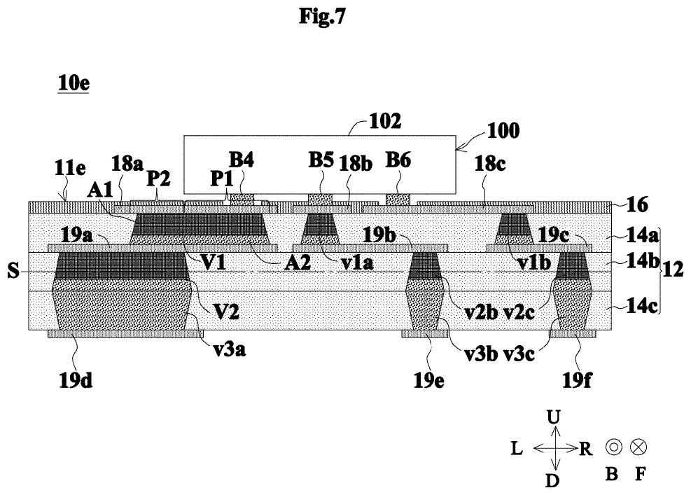

A multilayer board 11e according to a fifth modified example of an example embodiment of the present invention will be described below with reference to the drawings. FIG. 7 is a sectional view of a multilayer board module 10e.

The multilayer board 11e differs from the multilayer board 11a in the following points.
The multilayer board 11e includes a second interlayer connection conductor V2 instead of the second interlayer connection conductor v2a.
The second interlayer connection conductors v2b and v2c have higher thermal conductivity than the second regions A2.

The second interlayer connection conductor V2 has the same or substantially the same structure as the first interlayer connection conductor V1. Thus, the second interlayer connection conductor V2 includes a first region A1 and a second region A2. The upper end of the second interlayer connection conductor V2 is connected to the conductor layer 19a. The second interlayer connection conductor V2 includes the portion overlapping the first interlayer connection conductor V1 when viewed in the up-down direction and the portion not overlapping the first interlayer connection conductor V1 when viewed in the up-down direction.

Each of the second interlayer connection conductors v2b and v2c includes a first region A1 and a second region A2. The other structure of the multilayer board 11e is the same or substantially the same as that of the multilayer board 11a, and hence description thereof is omitted. The multilayer board 11e is capable of providing the advantageous effects (a) to (f).

In addition, since the multilayer board 11e includes the second interlayer connection conductor V2 having a large area when viewed in the up-down direction, it improves the heat dissipation characteristic of the multilayer board 11e. In the multilayer board 11e, the second interlayer connection conductor V2 includes the portion overlapping the first interlayer connection conductor V1 when viewed in the up-down direction and the portion not overlapping the first interlayer connection conductor V1 when viewed in the up-down direction. With this configuration, heat is transferred from the first interlayer connection conductor V1 to the portion of the second interlayer connection conductor V2 overlapping the first interlayer connection conductor V1 when viewed in the up-down direction. Then, heat is transferred from the portion of the second interlayer connection conductor V2 overlapping the first interlayer connection conductor V1 when viewed in the up-down direction to the portion of the second interlayer connection conductor V2 not overlapping the first interlayer connection conductor V1 when viewed in the up-down direction. In other words, heat is transferred in the multilayer body 12 in the right-left direction and the front-rear direction. This improves the heat dissipation characteristic of the multilayer board 11e.

### Sixth Modified Example

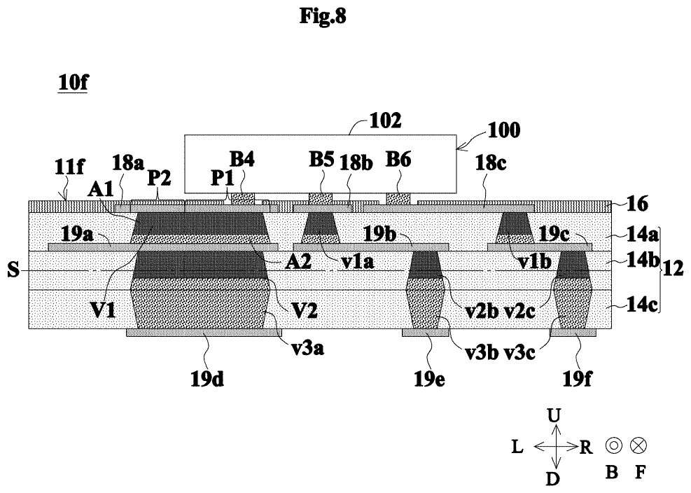

A multilayer board 11f according to a sixth modified example of an example embodiment of the present invention will be described below with reference to the drawings. FIG. 8 is a sectional view of a multilayer board module 10f.

The multilayer board 11f differs from the multilayer board 11e in that the entire or substantially the entire portion of the second interlayer connection conductor V2 overlaps the entire or substantially the entire portion of the first interlayer connection conductor V1 when viewed in the up-down direction. The other structure of the multilayer board 11f is the same or substantially the same as that of the multilayer board 11, and hence description thereof is omitted. The multilayer board 11f is capable of providing the advantageous effects (a) to (f). In addition, since the multilayer board 11f includes the second interlayer connection conductor V2 having a large area when viewed in the up-down direction, it improves the heat dissipation characteristic of the multilayer board 11f.

### Seventh Modified Example

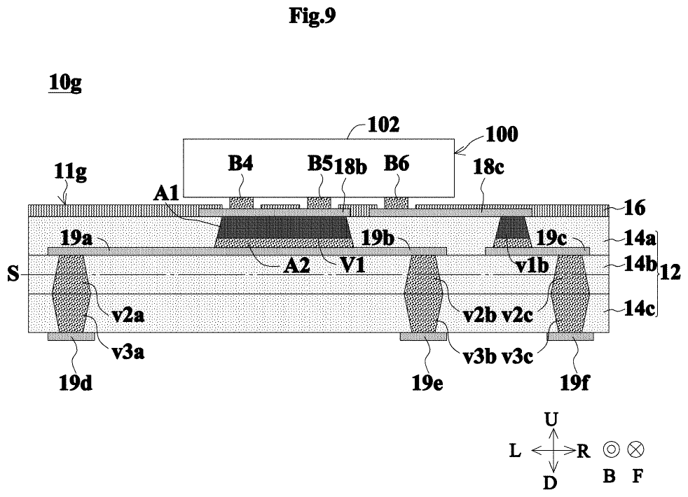

A multilayer board 11g according to a seventh modified example of an example embodiment of the present invention will be described below with reference to the drawings. FIG. 9 is a sectional view of a multilayer board module 10g.

As in the multilayer board 11g, the entire or substantially the entire portion of the first interlayer connection conductor V1 (the large-area first interlayer connection conductor) may overlap the electronic component 100 when viewed in the up-down direction. The multilayer board 11g is capable of providing the advantageous effects (a) to (f).

### Eighth Modified Example

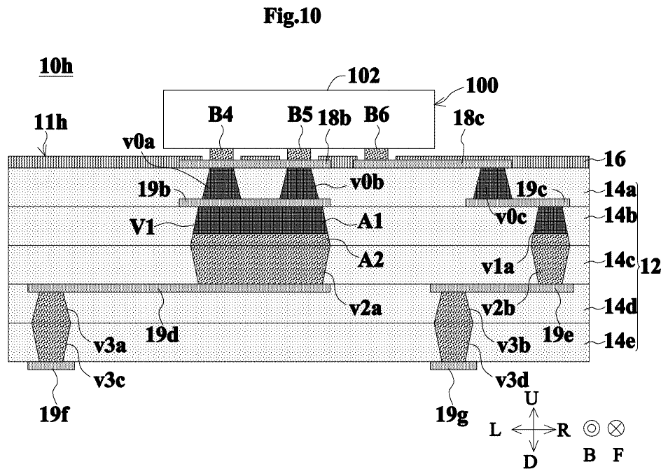

A multilayer board 11h according to an eighth modified example of an example embodiment of the present invention will be described below with reference to the drawings. FIG. 10 is a sectional view of a multilayer board module 10h.

As in the multilayer board 11h, a configuration in which a first interlayer connection conductor V1 (a large-area first interlayer connection conductor) is not directly connected to the conductor layer 18b (the first conductor layer) is also possible. In other words, the first interlayer connection conductor V1 (the large-area first interlayer connection conductor) may be connected to the conductor layer 18b (the first conductor layer) with conductors interposed therebetween. The conductors refer to the conductor layer 19b and interlayer connection conductors v0a and v0b. The interlayer connection conductors v0a and v0b extend through the insulator layer 14a in the up-down direction and connect the conductor layer 18b and the conductor layer 19b. The multilayer board 11h is capable of providing the advantageous effects (a) to (f).

### Ninth Modified Example

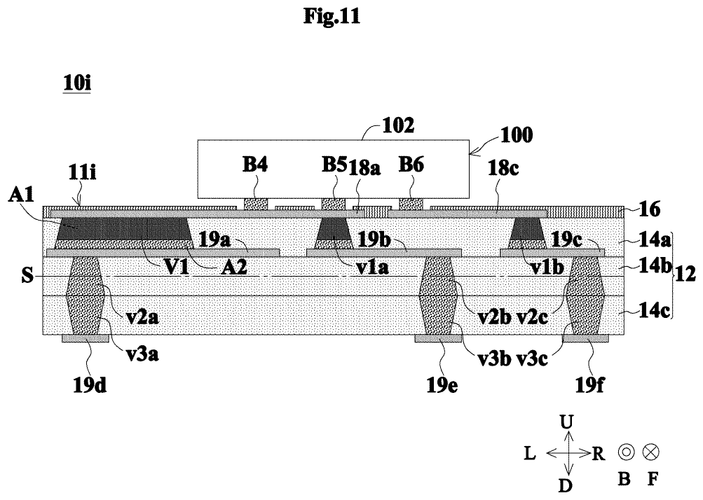

A multilayer board 11i according to an ninth modified example of an example embodiment of the present invention will be described below with reference to the drawings. FIG. 11 is a sectional view of a multilayer board module 10i.

As in the multilayer board 11i, a configuration in which a first interlayer connection conductor V1 (a large-area first interlayer connection conductor) does not overlap the electronic component 100 when viewed in the up-down direction is also possible. With this configuration, heat is diffused to positions away from the electronic component 100 due to the first interlayer connection conductor V1. This improves the heat dissipation characteristic of the multilayer board 11i. The multilayer board 11i is capable of providing the advantageous effects (a) to (f).

### Tenth Modified Example

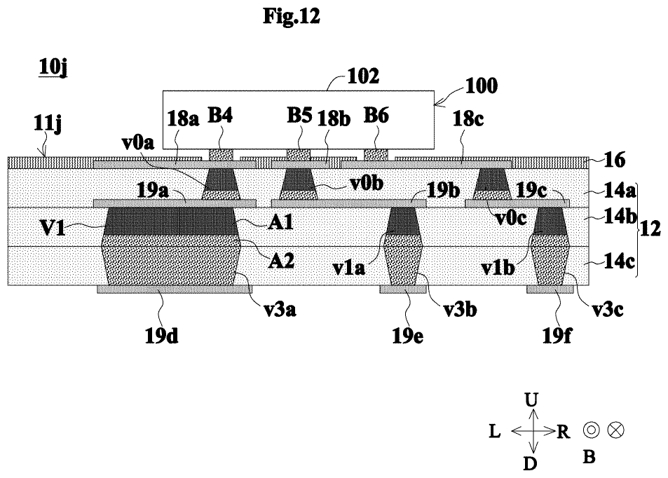

A multilayer board 11j according to a tenth modified example of an example embodiment of the present invention will be described below with reference to the drawings. FIG. 12 is a sectional view of a multilayer board module 10j.

As in the multilayer board 11j, a configuration in which a first interlayer connection conductor V1 (a large-area first interlayer connection conductor) is not directly connected to the conductor layer 18a (the first conductor layer) is also possible. In other words, the first interlayer connection conductor V1 (the large-area first interlayer connection conductor) may be connected to the conductor layer 18a (the first conductor layer) with conductors interposed therebetween. The conductors refer to the conductor layer 19a and an interlayer connection conductor v0a. The interlayer connection conductor v0a extends through the insulator layer 14a in the up-down direction and connects the first interlayer connection conductor V1 (the large-area first interlayer connection conductor) and the conductor layer 19a. The multilayer board 11h is capable of providing the advantageous effects (a) to (f).

### Eleventh Modified Example

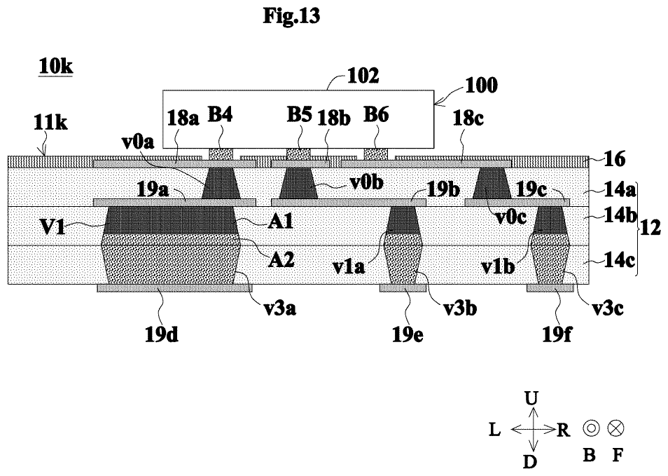

A multilayer board 11k according to an eleventh modified example of an example embodiment of the present invention will be described below with reference to the drawings. FIG. 13 is a sectional view of a multilayer board module 10k.

The multilayer board 11k differs from the multilayer board 11j in that interlayer connection conductors v0a to v0c have higher thermal conductivity than the second regions A2. The material of the interlayer connection conductors v0a to v0c is, for example, copper. With this configuration, heat generated in the electronic component 100 is efficiently transferred to a first interlayer connection conductor V1 (a large-area first interlayer connection conductor) through the interlayer connection conductors v0a to v0c interposed therebetween. The multilayer board 11k is capable of providing the advantageous effects (a) to (f).

### Twelfth Modified Example

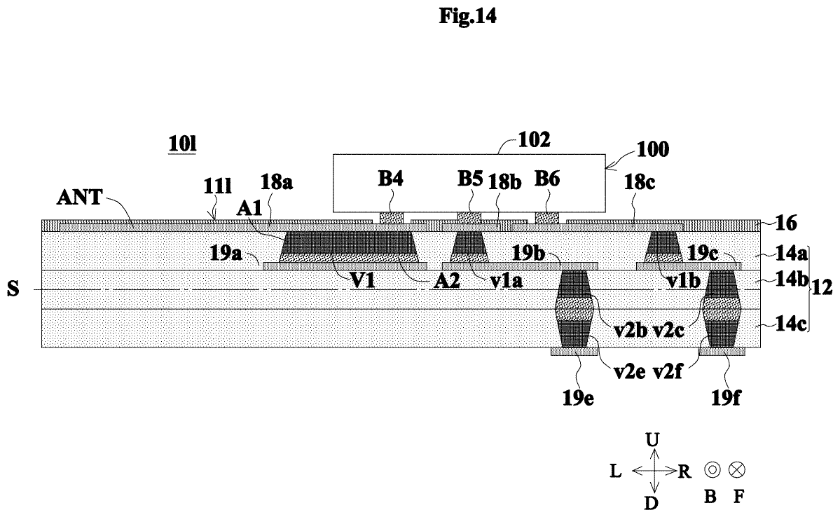

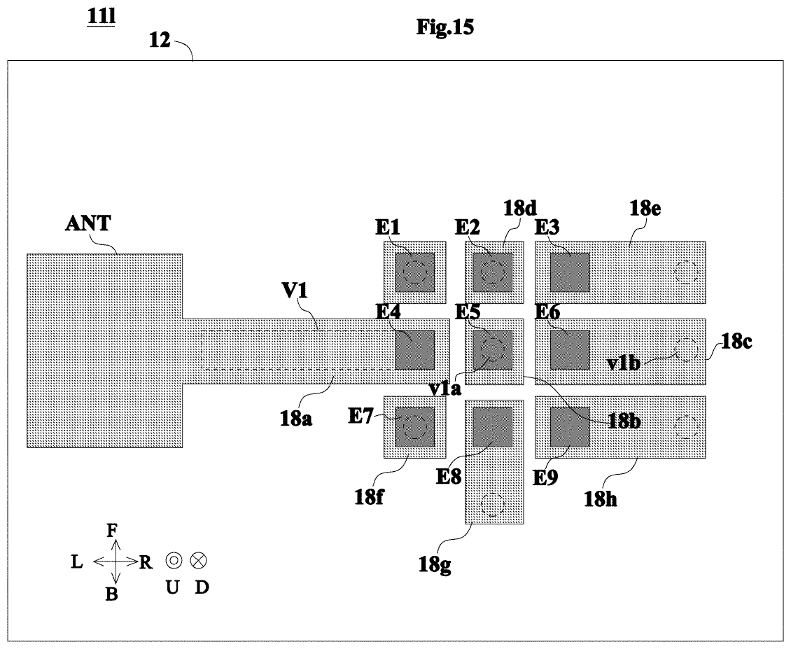

A multilayer board 11l according to a twelfth modified example of an example embodiment of the present invention will be described below with reference to the drawings. FIG. 14 is a sectional view of a multilayer board module 101. FIG. 15 is a top view of the multilayer board 11l.

As in the multilayer board 11l, a conductor layer 18a may include an antenna ANT. A first interlayer connection conductor V1 (a large-area first interlayer connection conductor) is connected to the conductor layer 18a. The first interlayer connection conductor V1 is located on a current path between an electronic component 100 and the antenna ANT. Thus, the resistance of the current path between the electronic component 100 and the antenna ANT is low. This reduces the heat generated in the current path between the electronic component 100 and the antenna ANT. The multilayer board 11l is capable of providing the advantageous effects (a) to (f).

In addition, the antenna ANT has a large area, and heat is efficiently radiated from the antenna ANT.

### Thirteenth Modified Example

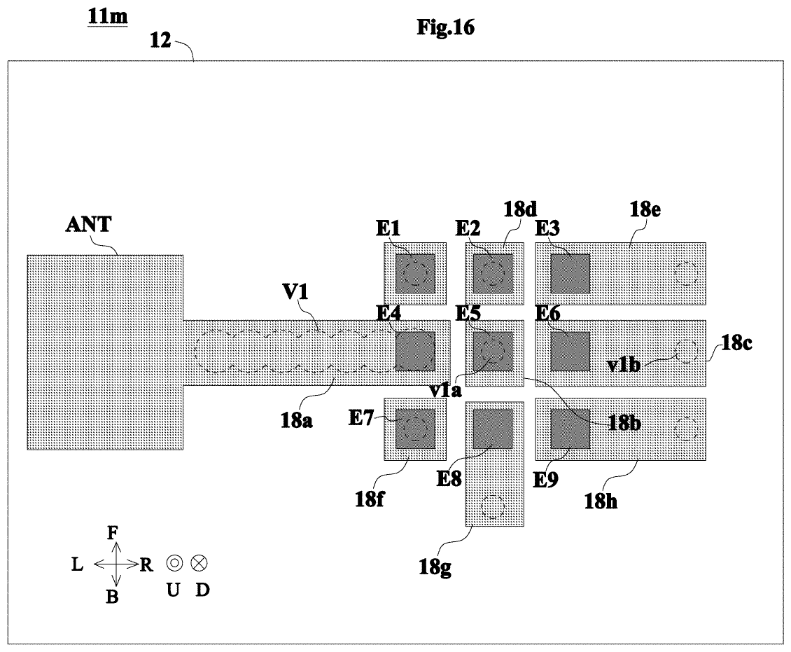

A multilayer board 11m according to a thirteenth modified example of an example embodiment of the present invention will be described below with reference to the drawings. FIG. 16 is a top view of a multilayer board module 10m.

The multilayer board 11m differs from the multilayer board 11l in the shape of a first interlayer connection conductor V1. To be more specific, in the multilayer board 11l, the first interlayer connection conductor V1 has a rectangular or substantially rectangular shape the long sides of which extend in the right-left direction when viewed in the up-down direction. In the multilayer board 11m, the first interlayer connection conductor V1 has a shape including a plurality of circles aligned in a row in the right-left direction when viewed in the up-down direction. The first interlayer connection conductor V1 is formed by, for example, forming a plurality of circular holes by drilling or irradiation of a laser beam. The multilayer board 11m is capable of providing the same or substantially the same operational advantages as the multilayer board 11l.

### Fourteenth Modified Example

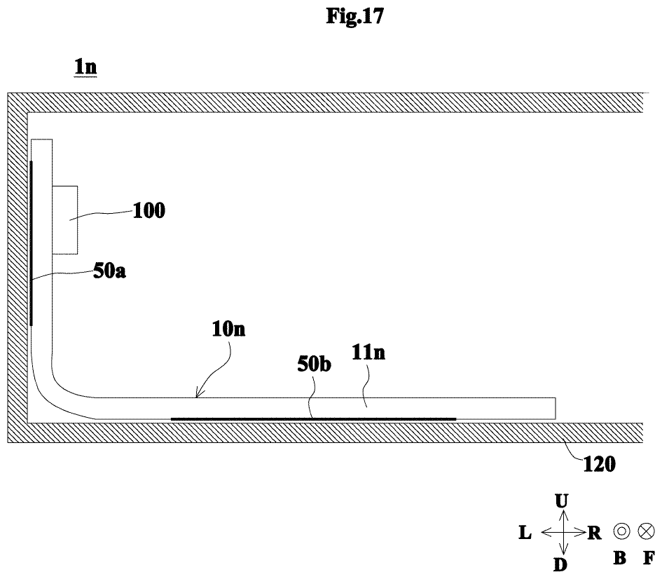

A multilayer board 11n according to a fourteenth modified example of an example embodiment of the present invention will be described below with reference to the drawings. FIG. 17 is a sectional view of an electronic device 1n.

The multilayer board 11n differs from the multilayer board 11 in that a plurality of conductor layers include antenna conductor layers 50a and 50b. The distance from the lower main surface (the negative main surface) of the multilayer body 12 to the antenna conductor layers 50a and 50b is shorter than the distance from the upper main surface (the positive main surface) of the multilayer body 12 to the antenna conductor layers 50a and 50b. The distance from the lower main surface of the multilayer body 12 to the housing 120 is shorter than the distance from the upper main surface of the multilayer body 12 to the housing 120.

In addition, the distance from the housing 120 to the lower main surface (the negative main surface) of the multilayer body 12 is shorter than the distance from the housing 120 to the upper main surface (the positive main surface) of the multilayer body 12. This configuration reduces transfer of heat generated in the electronic component 100 to the housing 120.

### Other Example Embodiments

The multilayer boards according to the present invention are not limited to the multilayer boards 11 and 11a to 11n and may be changed within a range of the spirit thereof. The structures of the multilayer boards 11 and 11a to 11n may be combined in any suitable manner.

A multilayer board includes one large-area first interlayer connection conductor. However, a multilayer board may include a plurality of large-area first interlayer connection conductors. In this case, the plurality of large-area first interlayer connection conductors may be located in the positive region A11. All of the large-area first interlayer connection conductors may be connected to the first conductor layer, or one or more of the large-area first interlayer connection conductors may be connected to the first conductor layer.

A multilayer board includes three third interlayer connection conductors. However, a multilayer board may include one or more third interlayer connection conductors.

A multilayer board includes six fourth interlayer connection conductors. However, a multilayer board may include one or more fourth interlayer connection conductors.

A multilayer board includes three fifth interlayer connection conductors. However, a multilayer board may include one or more fifth interlayer connection conductors.

A plurality of conductor layers may include an antenna.

A first interlayer connection conductor V1 has a rectangular or substantially rectangular shape when viewed in the up-down direction as in the first interlayer connection conductor V1 in FIG. 2. However, a first interlayer connection conductor V1 may have a shape other than a rectangular or substantially rectangular shape when viewed in the up-down direction. A first interlayer connection conductor V1 when viewed in the up-down direction may have, for example, a polygonal shape, a circular shape, or the like or a shape the outer edges of which have protrusions or recesses.

An antenna ANT may be, for example, a patch antenna, a dipole antenna, a monopole antenna, or a slot antenna.

Second interlayer connection conductors may be located in a first insulator layer where first interlayer connection conductors are located.

A multilayer board may further include a protective layer covering the lower main surface of the multilayer body 12.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer board comprising:
a multilayer body including a plurality of insulator layers laminated in a Z-axis direction and including a positive main surface located on a Z-axis positive direction side and a negative main surface located on a Z-axis negative direction side;
a plurality of conductor layers in or on the multilayer body and including a first conductor layer including a mounting electrode located on a positive main surface of an insulator layer located farthest in a Z-axis positive direction out of the plurality of insulator layers;
one or more first interlayer connection conductors extending through a first insulator layer included in the plurality of insulator layers in the Z-axis direction and connecting two of the plurality of conductor layers located on a positive main surface and a negative main surface of the first insulator layer; and
a second interlayer connection conductor extending through one of the plurality of insulator layers in the Z-axis direction; wherein
each of the one or more first interlayer connection conductors includes:
a first region; and
a second region with lower thermal conductivity than the first region and located on the Z-axis negative direction side of the first region; and
the one or more first interlayer connection conductors include one or more large-area first interlayer connection conductors each with a larger area than the second interlayer connection conductor when viewed in the Z-axis direction.

2. The multilayer board according to claim 1, wherein the one or more large-area first interlayer connection conductors are connected to the first conductor layer with a conductor interposed in between or directly connected to the first conductor layer.

3. The multilayer board according to claim 1, wherein, when a plane located at a center or an approximate center of the multilayer body in the Z-axis direction and orthogonal or substantially orthogonal to the Z-axis direction is defined as an intermediate plane, the one or more large-area first interlayer connection conductors are located on the Z-axis positive direction side of the intermediate plane.

4. The multilayer board according to claim 1, wherein
when a plane located at a center or an approximate center of the multilayer body in the Z-axis direction and orthogonal or substantially orthogonal to the Z-axis direction is defined as an intermediate plane, the multilayer board includes:
one or more third interlayer connection conductors extending through one of the plurality of insulator layers in the Z-axis direction and located on the Z-axis negative direction side of the intermediate plane; and
the one or more third interlayer connection conductors have lower thermal conductivity than the first region.

5. The multilayer board according to claim 1, wherein, when the multilayer body is trisected in the Z-axis direction into a positive region, an intermediate region, and a negative region, and the positive region, the intermediate region, and the negative region are located in a Z-axis negative direction in order of the positive region, the intermediate region, and the negative region, the one or more large-area first interlayer connection conductors are located in the positive region.

6. The multilayer board according to claim 5, further comprising:
one or more fourth interlayer connection conductors extending through one of the plurality of insulator layers in the Z-axis direction and located in the intermediate region;
wherein the one or more fourth interlayer connection conductors have lower thermal conductivity than the first region.

7. The multilayer board according to claim 6, further comprising:
one or more fifth interlayer connection conductors extending through one of the plurality of insulator layers in the Z-axis direction and located in the negative region; wherein
the one or more fifth interlayer connection conductors have higher thermal conductivity than the second region.

8. The multilayer board according to claim 1, wherein at least one of the plurality of conductor layers connected to the one or more large-area first interlayer connection conductors includes an antenna.

9. The multilayer board according to claim 1, wherein the multilayer body has flexibility.

10. The multilayer board according to claim 1, wherein
the plurality of conductor layers include an antenna conductor layer; and
a distance from the negative main surface to the antenna conductor layer is shorter than a distance from the positive main surface to the antenna conductor layer.

11. The multilayer board according to claim 1, wherein at least one of the one or more large-area first interlayer connection conductors is directly connected to the first conductor layer.

12. The multilayer board according to claim 1, wherein a power supply voltage or a ground potential is connected to the one or more large-area first interlayer connection conductors.

13. A multilayer board module comprising:
the multilayer board according to claim 1; and
an electronic component mounted on the mounting electrode.

14. The multilayer board module according to claim 13, wherein
at least one of the one or more large-area first interlayer connection conductors includes an overlapping portion overlapping the electronic component when viewed in the Z-axis direction and a non-overlapping portion not overlapping the electronic component when viewed in the Z-axis direction.

15. The multilayer board module according to claim 13, wherein the electronic component is an RFIC.

16. An electronic device comprising:
the multilayer board module according to claim 13.

17. The electronic device according to claim 16, further comprising:
a housing to house the multilayer board module; wherein
a distance from the housing to the negative main surface is shorter than a distance from the housing to the positive main surface.

18. The electronic device according to claim 16, wherein the one or more large-area first interlayer connection conductors are connected to the first conductor layer with a conductor interposed in between or directly connected to the first conductor layer.

19. The electronic device according to claim 16, wherein, when a plane located at a center or an approximate center of the multilayer body in the Z-axis direction and orthogonal or substantially orthogonal to the Z-axis direction is defined as an intermediate plane, the one or more large-area first interlayer connection conductors are located on the Z-axis positive direction side of the intermediate plane.

20. The electronic device according to claim 16, wherein
when a plane located at a center or an approximate center of the multilayer body in the Z-axis direction and orthogonal or substantially orthogonal to the Z-axis direction is defined as an intermediate plane, the multilayer board includes:
one or more third interlayer connection conductors extending through one of the plurality of insulator layers in the Z-axis direction and located on the Z-axis negative direction side of the intermediate plane; and
the one or more third interlayer connection conductors have lower thermal conductivity than the first region.
